(19) United States
(12) Patent Application Publication
(10) Pub. No.: US 2007/0169701 A1
(43) Pub. Date: Jul. 26, 2007

(54) Tubular or Other Member Formed of Staves Bonded at Keyway Interlocks

(75) Inventors: Reese REYNOLDS, Los Gatos, CA (US); Michael SKLYAR, San Jose, CA (US)

Correspondence Address: LAW OFFICES OF CHARLES GUENZER, P O BOX 60729, PALO ALTO, CA, 94306, US

(73) Assignee: INTEGRATED MATERIALS, INC., Sunnyvale, CA (US)

(21) Appl. No.: 11/536,352

(22) Filed: Sep. 28, 2006

Related U.S. Application Data
(60) Provisional application No. 60/760,993, filed on Jan. 21, 2006.

(51) Int. Cl. C23C 16/00

(52) U.S. Cl. 118/724; 156/916

(57) ABSTRACT

A tubular member formed of silicon staves and arranged in a circular pattern to form a central bore in which a wafer support tower can be inserted for batch thermal processing in an oven. The staves are formed along an axis with an interlocking keyway structure in which axially extending hooks engage axially extending catches formed in back of the hooks on neighboring staves. An adhesive, such as a silica-forming agent and silicon powder, coat the keyway structure before assembly and is cured after assembly, so as to bond the staves together. A similar structure may be used to form a plate structure from an array of smaller parts with interlocking structure formed between neighboring parts.

### RELATED APPLICATION

This application claims benefit of provisional application 60/760,993, filed Jan. 21, 2006.

### FIELD OF THE INVENTION

The invention relates generally to equipment used in thermal processing of substrates. In particular, the invention relates to large structures used in semiconductor processing such as a tubular liner used in a thermal oven.

### BACKGROUND OF THE INVENTION

Batch thermal processing continues to be used for several stages of fabrication of silicon integrated circuits. One low temperature thermal process deposits a layer of silicon nitride by chemical vapor deposition, typically using chlorosilane and ammonia as the precursor gases at temperatures in the range of about 700° C. Other, high-temperature processes include oxidation, annealing, silicidation, and other processes typically using higher temperatures, for example above 1000° C. or even 1350° C.

For large-scale commercial production, vertical furnaces and vertically arranged wafer towers supporting a large number of wafers in the furnace are typically used, often in a configuration illustrated in the schematic cross-sectional view of FIG. 1. A furnace 10 includes a thermally insulating heater canister 12 supporting a resistive heating coil 14 powered by an unillustrated electrical power supply. A bell jar 16, typically composed of quartz, includes a roof and fits within the heating coil 14. An open-ended liner 18 fits within the bell jar 16. A support tower 20 sits on a pedestal 22 and during processing the pedestal 22 and support tower 20 are generally surrounded by the liner 18. It includes vertically arranged slots for holding multiple horizontally disposed wafers 19 to be thermally processed in batch mode. The diameter of the internal axially extending bore of liner 18 must be great enough to accommodate the wafers 19 and the support tower 20, that is, significantly greater than 200 mm for processing 200 mm wafers and significantly greater than 300 mm for processing 300 mm wafers. A gas injector 24 is principally disposed between the liner 18 has an outlet on its upper end for injecting processing gas within the liner 18. An unillustrated vacuum pump removes the processing gas through the bottom of the bell jar 16. The heater canister 12, bell jar 16, and liner 18 may be raised vertically to allow wafers to be transferred to and from the tower 20, although in some configurations these elements remain stationary while an elevator raises and lowers the pedestal 22 and loaded tower 20 into and out of the bottom of furnace 10.

The bell jar 16, which is closed on its upper end, tends to cause the furnace 10 to have a generally uniformly hot temperature in the middle and upper portions of the furnace. This region is referred to as the hot zone in which the temperature is controlled for the optimized thermal process. However, the open bottom end of the bell jar 18 and the mechanical support of the pedestal 22 causes the lower end of the furnace to have a lower temperature, often low enough that the thermal process such as chemical vapor deposition is not effective. The hot zone may exclude some of the lower slots of the tower 20.

Conventionally in low-temperature applications, the tower, liner, and injectors have been composed of quartz or fused silica. However, quartz towers and injectors are being supplanted by silicon towers, liners, and injectors. Silicon towers of somewhat different configurations for various applications and silicon injectors are commercially available from Integrated Materials, Inc. of Sunnyvale, Calif. and are disclosed respectively in U.S. Pat. No. 6,450,346 and U.S. patent application Ser. No. 11/177,808, filed Jul. 8, 2005 and published as U.S. Patent Publication 2006/0185589. Silicon liners present challenges in their fabrication because of their very large diameters and the general unavailability of high-purity silicon in such large sizes. However, Boyle et al. disclose an effective method of fabricating silicon liners from silicon staves in U.S. patent application Ser. No. 10/642,013, filed Sep. 26, 2001 and published as U.S. Patent Publication 2004/0129203, incorporated herein by reference in its entirety. Silicon is available in very high purity in the form of virgin polysilicon (electronic grade silicon) and thus contains very low levels of impurities. However, a silicon member is defined as comprising at least 95 at % and preferably at least 99 at % elemental silicon.

A silicon liner 30 may be formed by bonding together, as illustrated in the cross-sectional view of FIG. 2, sixteen or so silicon staves 32, which are long and thin, for example, 4 mm thick and 1 m long. Note that the early figures do not accurately portray the thinness of the staves. They are generally rectangular but to conform more closely to the polygonal shape they are somewhat trapezoidal. They are arranged in a closed polygonal (nearly circular) shape about a center 36 and bonded together to form a tubular member having a form similar to that of a wooden wine barrel. To accommodate a tower supporting 300 mm wafer, the liner 30 needs to have an internal diameter of approximately 350 mm. A very effective adhesive for bonding together silicon staves is a composite of a spin-on glass (SOG) and silicon powder, as disclosed by Boyle et al. in U.S. Pat. No. 7,083,694.

It is perhaps possible that the staves could have flat abutting surfaces. However, the staves must be aligned to each other during the high-temperature curing of the adhesive. Accordingly, the design was developed of a tongue-and-groove joint, illustrated in the sectional view of FIG. 3, in which each of two staves 40, 42 are formed with a V-shaped tongue 44 and a V-shaped groove 26 with flat areas 48 on opposed sides of the tongue 44 and grooves 46. The tongue 44 of the first stave 40 faces and mates with the groove 18 of the second stave 44. The adhesive is applied to the mating surfaces before the staves are assembled together and then annealed at an elevated temperature to cure the adhesive. Such silicon liners have been fabricated, but their assembly is long and difficult and the yield remains low.

### SUMMARY OF THE INVENTION

A multi-part structural member formed of bonded parts, particularly a tubular member formed of staves bonded together in a closed pattern, in which the joints are formed with interlocking members extending at least partially transversely to the plane of the parts or staves. A bonding agent may be applied to the joint before its assembly. The interlocking joint inhibits motion across the joint and facilitates alignment.

One embodiment of the interlocking mechanism includes an axially extending hook on each side of the stave or other part and a catch in back of the hook. The hook of one stave or part engages and interlocks with the catch of the neighboring stave or part. Advantageously, the radius of curvature at a corner of the hook is greater than that of the catch to produce a larger gap at the corner.

The invention is particularly useful for forming silicon liners and other large silicon tubes used in batch thermal processing furnaces used in the semiconductor industry. The bonding agent for silicon members may be a combination of a spin-on glass and silicon powder.

For tubular assemblies, the hooks on one stave may extend perpendicularly inward from an outer principal surface to facilitate assembly.

The invention is also useful for forming planar plates out of smaller members. Interlocking joints for planar assemblies may extend perpendicularly to the principal surfaces of the member or in some applications they are advantageously inclined.

### BRIEF DESCRIPTION OF THE DRAWINGS

FIG. 1 is a cross-sectional view of a furnace used for batch thermal processing of wafers and with which a liner of the invention may be used.

FIG. 2 is schematic cross-sectional view of a liner formed from staves bonded together to form a polygonal tube.

FIG. 3 is a cross-sectional view of a tongue-and-groove joint between staves.

FIG. 4 is a graph of the strength of different types of joints including a keyway joint of the invention.

FIG. 5 is a cross-sectional view of a V-shaped joint between staves.

FIG. 6 is a cross-sectional view of a keyway joint between two co-planar members.

FIG. 7 is an orthographic view of a liner formed with keyway joints and including an optional neck.

FIG. 8 is an exploded orthographic view of the neck of FIG. 7.

FIG. 9 is a cross-sectional view of a liner including one embodiment of the keyway joints.

FIGS. 10 and 11 are exploded cross-sectional views of two regions of the liner of FIG. 9 showing two types of staves forming the keyway joints.

FIG. 12 is a cross-sectional view of a keyway joint in the liner of FIG. 9.

FIG. 13 is another cross-sectional view the keyway joint of FIG. 12 showing clearances between the staves.

FIG. 14 is a cross-sectional view of a keyway joint used to assemble a planar sheet.

FIG. 15 is a cross-sectional view of an inclined keyway joint particularly useful in forming large planar plates and further showing its assembly on a horizontal table.

FIG. 16 is a cross-section view of an inclined keyway joint and its assembly on a tilted table.

### DETAILED DESCRIPTION OF THE PREFERRED EMBODIMENTS

We have developed a jig to support and align eight staves with the uncured adhesive applied to the joint area. The jig includes at least two sets of T-shaped studs supported at different angles by an arc-shaped base at their bottoms and supporting different ones of the staves at their tops. The staves supported by the jig and sandwiching the uncured adhesive between the staves are then annealed to form a rigid semi-tubular member. The process is then repeated to form the other half and join it to the first half. The gap between the staves in which the adhesive pools and is cured should be kept thin, preferably about 35 μm. We have found it very difficult to maintain both the gap spacing and the proper orientation over the entire length and circumference of the uncured tubular assembly. The required cumulative accuracy for the sixteen staves of a standard design of a liner is about 80 μm and the angular resolution if about ±0.01°. We believe that the angular precision needs to be decoupled from the spatial precision.

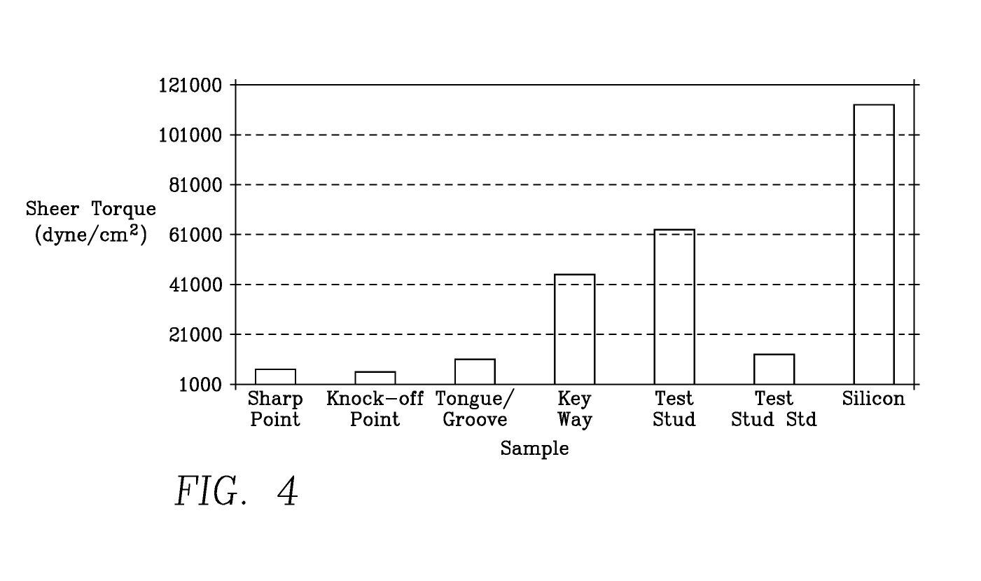

An overall measure of the integrity of a joint is the sheer torque before the joint breaks. A bar chart for sheer torque limits for various joints is presented in FIG. 4 in units of dyne/cm². For comparison, a solid piece of annealed virgin polysilicon (electronic grade silicon) breaks at about 110,000. For determining the effectiveness of a fusion process, a test stud procedure has been developed in which two rectangular silicon members are fused across a planar interface. We have imposed a standard of about 6000 but have routinely achieved above 60,000 as the process has solidified. The tongue and groove configuration for two co-planar staves, however, regularly fails at about 4000.

A first approach attempts to emulate a ball-and-socket joint that allows the jig to provide the angular resolution and the joint to provide the spatial resolution. As illustrated in the cross-sectional view of FIG. 5, each stave 50 is formed with a convex V-shaped side 52 and a concave V-shaped side 54 which mate with each other with the adhesive filling a gap 56 between them. There is substantially no flat areas on the edges of the V shapes. The test staves were generally rectangular to form a planar assembly to simplify the torque tests. This design allows a substantial angular movement determined by the jig without the gap 56 being made severely non-uniform. The sheer tests displayed in FIG. 4 showed poor results with breakage occurring around 4000.

A second approach knocks off the acute end 58 of the convex V-shaped side 52 so that the tip is more rounded. The sheer tests, however, showed even poorer results.

A preferred third approach uses a keyway design, illustrated in the cross-sectional view of FIG. 6. Staves 60, 62 are formed with ends having interlocking hook structures. Each stave 60, 62 includes a hook 64 and a catch 66 in back of the hook 64 for retaining the hook 64 of the other stave 62, 60. That is, the hooks 64 point in different directions when the two staves 60, 62 are assembled together in a pair. The assembled hooks 64 and catches 66 form an interlocking joint between the two staves 60, 62 which prevents their separation in a direction parallel to the principal faces of the staves 60, 62 away from the joint. In this embodiment, both the hook 64 and the catch 66 have substantially rectangular shapes so that the retaining side is perpendicular to the side along which the staves 60, 62 can slide over each other. The hooks 64 and catches 66 are dimensioned such that the two staves 60, 62 may be assembled together with a predetermined gap 68 between them, which is pre-filled with the adhesive filling the gap 68. The gap 68 is typically thinner than as illustrated. In the present designs, the nominal gap is about 35 μm but after completion of machining and surface roughening and cleaning a final gap of about 60 to 70 μm is obtained. It is believed that a final gap of 40 to 100 μm is acceptable. With further developments in the adhesive technology, this gap maybe further decreased.

The test structure for the third approach was fabricated and fused. The torque tests shown in FIG. 3 show a strength above 40,000 for the keyway design, that is, substantially in excess of the strengths of the tongue-and-groove joint and the test stud standard and nearly as much as the observed results for advanced test studs. Generally, the test structure showed great rigidity and tends to break in the silicon, presumably in the thin silicon arm in back of the catch 66.

We believe, although the invention is not bound by our understanding, that part of the strength of the keyway joint arises from the fusion of the adhesive to silicon in a blind joint 70 separated from the exterior by two right-angle turns on each side of the hook 66.

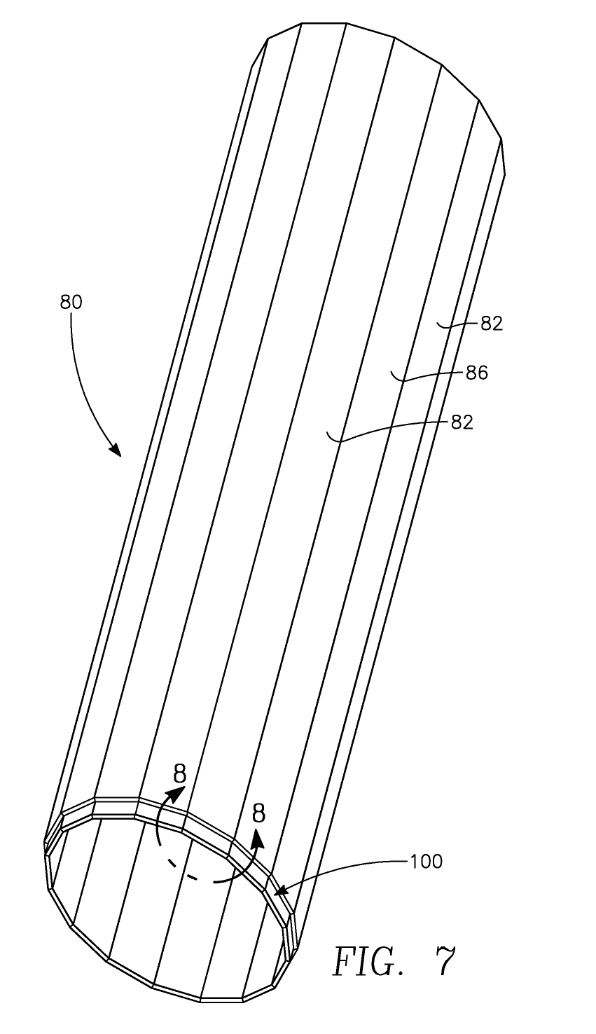

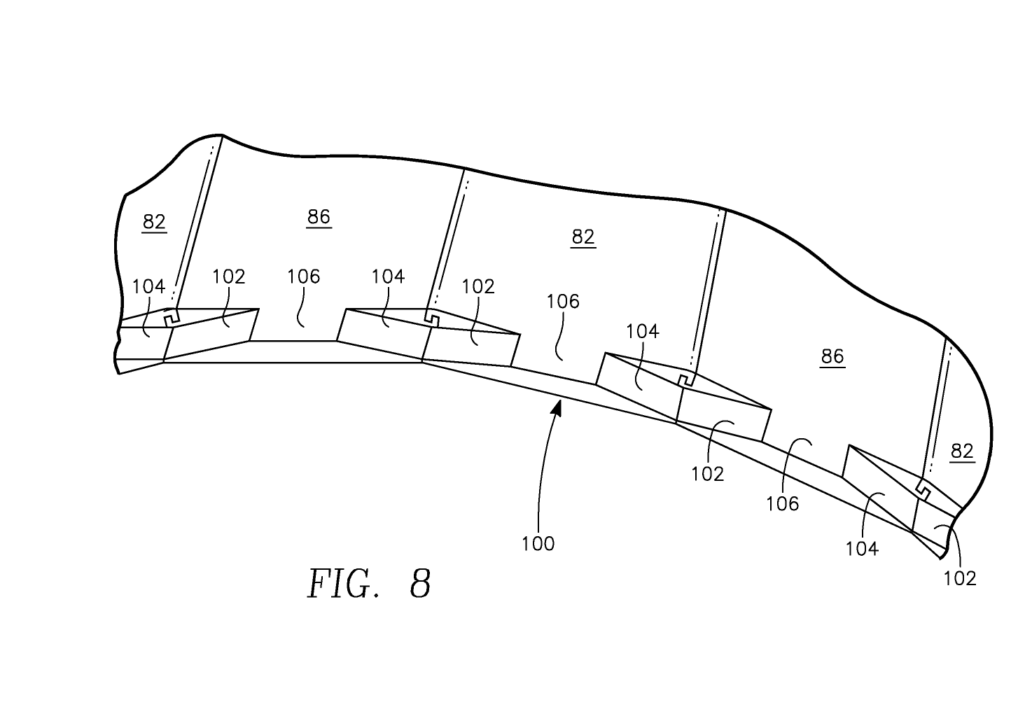

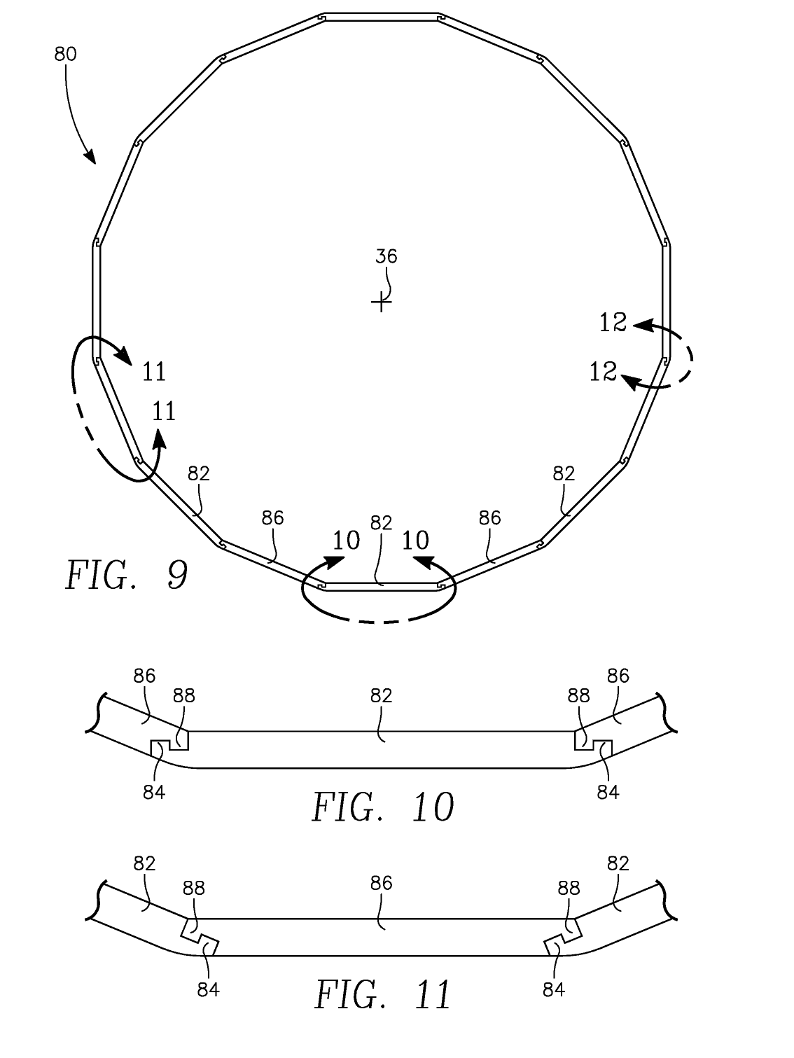

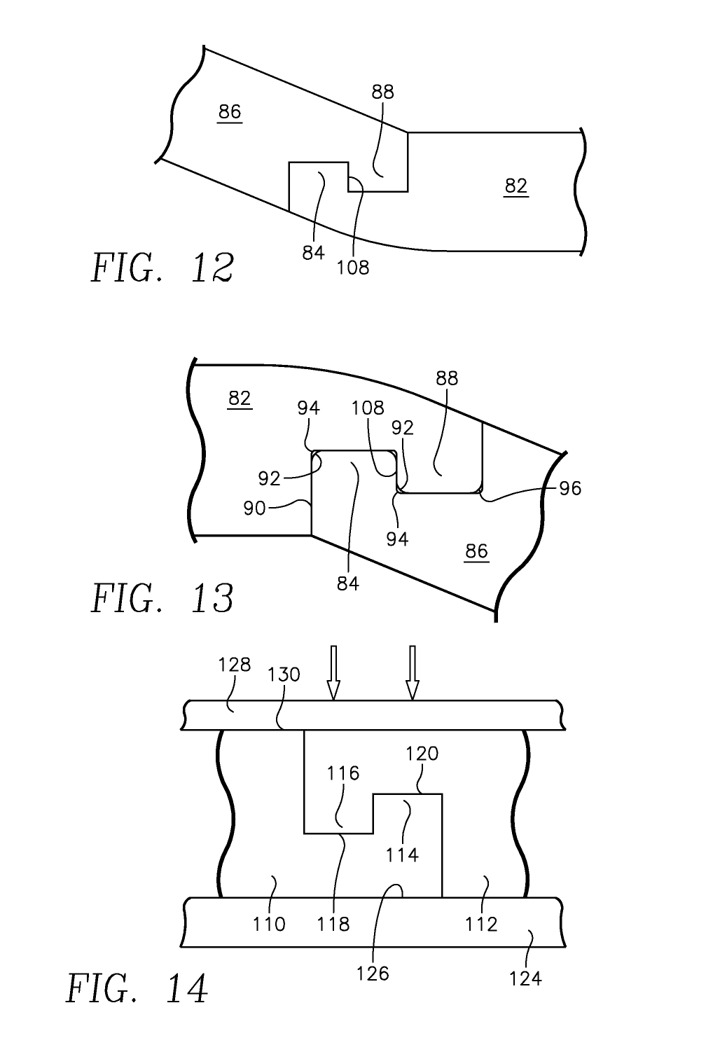

The planar test structure of FIG. 6 needs to be adapted to the closed polygonal shape of a tube and the need to accurately assemble the staves together. One keylocked tube 80 is illustrated in the orthographic view of FIG. 7, its exploded view of FIG. 8, and the axial cross-sectional view of FIG. 9. FIGS. 10 and 11 are exploded views of FIG. 9, and FIG. 12 is a further exploded view of a keyway joint of FIG. 10. The keylocked tube 80 requires two types of alternating staves although a single type may suffice for other embodiments. Staves 82 have inwardly directed hooks 84. Staves 86 have outwardly directed hooks 88. The hooks 84, 88 axially extend as ridges along the length of the staves 82, 86 and along the central axis of the tube 80 when assembled. Further, both hooks 84, 88, when assembled, extend perpendicularly to the major surface of the stave 82. The orientations of the hooks and associated catches facilitate the assembly of the last hook-inward stave 82 onto the neighboring two already aligned hook-outward staves 86 to complete the tube if the assembly is done from the outside. Assembly from the interior would be facilitated if the hooks extend perpendicularly to the principal surface of the last assembled stave.

A further enlarged cross-sectional view of the keyway joint shown in FIG. 13 illustrates a predetermined small gap 90 between the staves 82, 86 around the hooks 84, 88 to allow for assembly and for the volume of the adhesive. Additionally, the radius of convex corners 92 of the hooks 84, 88 is greater than the radius of corresponding concave corners 94 of the catches so that enlarged corner gaps 96 can accommodate an overflow of the adhesive from the flat portion portions of the gap 90, which flat portions provide most of the mechanical strength to the keyway joint.

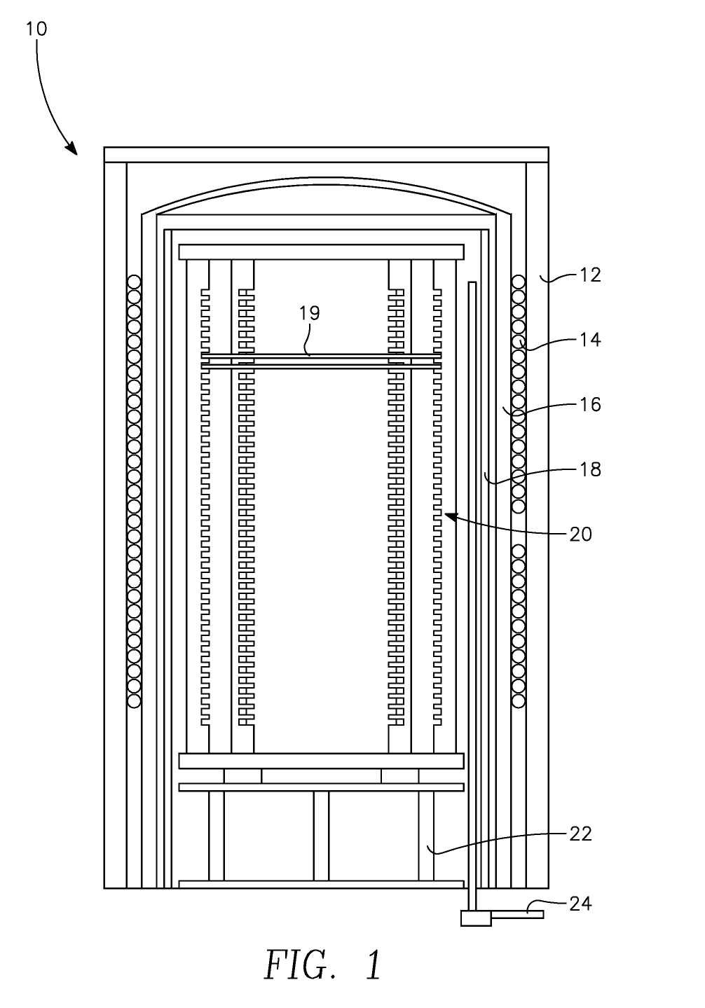

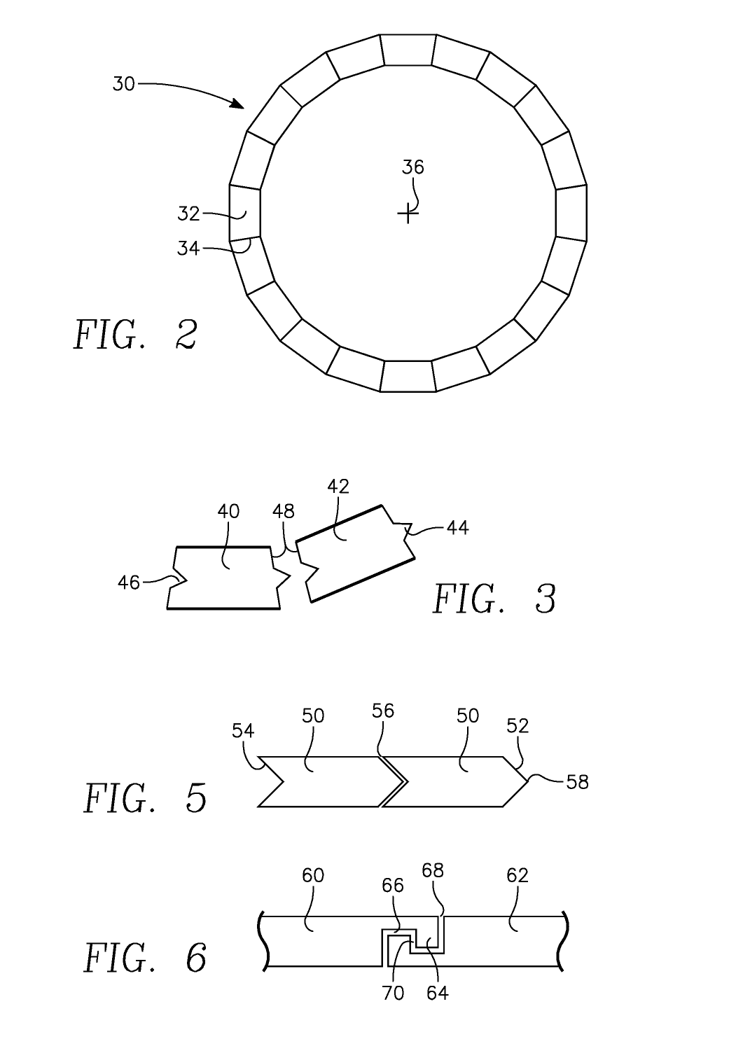

As is evident in FIGS. 7 and 8, the staves 82, 86 may be shaped formed to form an optional outer neck 100 on the lower outer side of the liner 80. The neck 100 is sized such that the liner 80 can be held at its lower end within a circular stainless steel or other type of collar on top of the pedestal 22 of FIG. 1 used in some types of furnaces. However, other furnaces include support platforms not requiring the neck 100. The neck 100 maybe formed, as best illustrated in FIG. 8, by machining the bottom ends of the staves 82, 86 to have two side chamfers 102, 104 with a central flat ridge 106 extending from the principal outer surface of the staves 82, 86. The chamfers 102, 104 and ridge 106 have equal circumferential widths and are equally angularly oriented with respect to the liner center 36 so that when the liner 80 is assembled the chamfers 102, 104 and central flat area 106 approximate a circularly symmetric surface of the neck 100. The staves 82, 86 can be formed into more than three such angularly differentiated portions to better approximate a circle and, if desired, the staves 82, 86 maybe machined to have a purely circular neck 100.

The structure of tube 80 provides several advantages. There is some angular flexibility between the staves which can be aligned by the jig. As illustrated in FIG. 13, a double-blind flat joint 108, that is, having two acute turns to the exterior, between adjacent hooks 84, 88 produces a good fusion between the staves 82, 88 through the cured composite adhesive. The size of the gap between the staves 82, 88 and hence the thickness of the adhesive can in large part be determined by the initial machining of the staves 82, 86. The interlocking hooks provides some self-assembly and self-alignment in the circumferential as well as radial directions, thus simplifying the assembly and alignment.

Other designs are possible. Each stave may be formed with hooks facing in opposed directions on the two ends. This design simplifies the fabrication and inventory of staves but presents a challenge in assembling the last, closing stave. Additional hooks and catches maybe added on each end. The hooks and catches do not require a completely rectangular form.

Although the invention is particularly useful for fusing tubular silicon members, it may be applied to other uses. The interlocking mechanism may be applied to planar members that need to be joined together into a larger planar structure of a one- or two-dimensional array. As illustrated in the cross-sectional view of FIG. 14, two co-planar silicon plates 110, 112 are joined at an interlocking mechanism in which the plates 110, 112 includes respective hooks 114, 116 and catches 118, 120 respectively engaging the hooks 116, 114 of the other plate 112, 110. The plates 110, 112 are bonded together to form a planar sheet. A double-blind joint promotes a strong adhesive bonding of the two plates 110, 112. A similar interlocking mechanism may be applied to the other side of one or both of the plates 110, 112 to form larger sheets or three, four, or more plates. As a result, large silicon sheets can be fused from smaller silicon plates with the interlocking mechanism providing both alignment and a predetermined gap between neighboring ones of the plates. The large bonded sheets can be used to form gas showerheads or liner covers, as disclosed by Cadwell et al. in provisional application 60/765,013, filed Feb. 3, 2006.

The fusing of the two or more plates 110, 112 can be accomplished by coating the keyway joint between the plates 110, 112 with the uncured adhesive and assembling the pre-coated plates 110, 112 on an assembly table 124 supporting bottom surfaces 126 of the plates 110, 112. A press plate 128 applies pressure to top surfaces 130 of the plates 110, 112 to align the plates 110, 112 and press excess adhesive out of the joint. After the plates have been bonded together into a sheet with any necessary curing of the adhesive, the sheet may be machined, for example, rounded and bored between its principal surfaces with a plurality of showerhead jet holes or machined to form apertures in the liner cover.

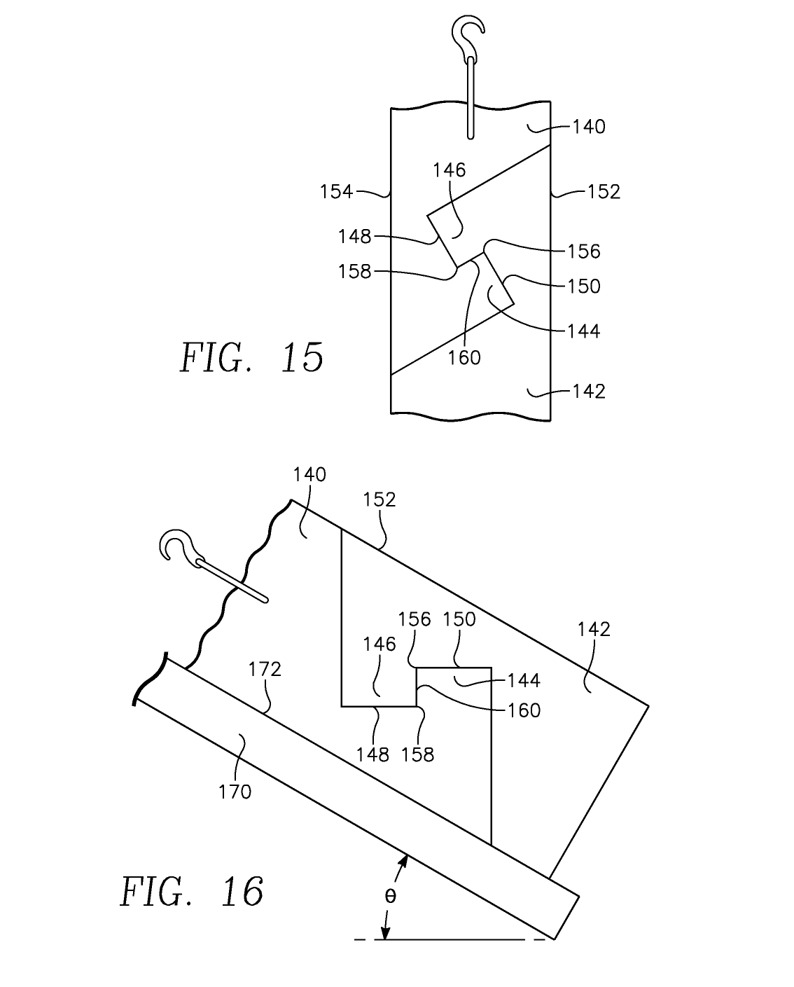

In the interlocking mechanism of FIG. 14, the hooks and catches extended generally perpendicularly to the principal planes of the plates 110, 112. Another interlocking mechanism, illustrated in the cross-sectional view of FIG. 15, is particularly useful for assembling plates to form a planar sheet. Two generally planar parts 140, 142 are formed with inclined acute hooks 144, 146 and corresponding catches 148, 150 that have surfaces which are perpendicular to each other but are inclined with respect to opposed principal surfaces 152, 154 of the parts 140, 142. After the keyway joints of two or more parts 140, 142 have been pre-coated with uncured adhesive, they are assembled vertically with the uppermost part 140 being supported from above by mechanical holding means, including for example the illustrated hangar hook engaged to a fixed support, and with the hooks 144, 146 engaging corresponding catches 148, 150. Neither an assembly table nor a press plate is required. If desired, an inclined downward vertical load can be additionally imposed on the bottommost part 142. The inclined hooks 144, 146 and catches 148, 150 under gravitational force and the optional downward load align the parts 140, 142 and force hooks 144, 146 into respective corners 156, 158 of the other part 140, 142. The predetermined space between the parts 140, 142 filled with the adhesive is not clearly illustrated in FIG. 15. A double-blind flat joint 160, across which the parts 140, 142 are pulled, provides for a well fused junction across the cured adhesive.

Alternatively, as illustrated in the cross-sectional view of FIG. 16, the parts 140, 142 can be glued and assembled on an assembly table 170 that is tilted at an angle 0 from the horizontal and supports bottom surfaces 172 of the parts 140, 142. The uppermost part 140 is fixed against sliding downwardly on the tilted table 170 and an additional partially downward load can be imposed on the bottommost part 142 to thereby force the parts together and align them on the table 170. A press plate may be additionally used but is not required.

The material of the parts assembled joined by the keyway interlocks need not be silicon. The invention is not limited to virgin polysilicon staves or even to silicon staves or other silicon members. Other materials may be used. Further, the method interlocking assembly may be applied to aligning members to be welded by electrical or laser means, particularly into tubular structures such as need for liners.

The invention thus provides relatively simple means to expedite assembly and assure alignment of parts to be bonded together.

1. A structure comprising a plurality of members meeting at a joint between neighboring members which are bonded together adjacent the joint, each joint including an interlocking structure formed within and between both of the neighboring members.

2. The structure of claim 1, wherein each of the members includes two hooks and two catches in back of the hooks in which hooks of other members are engaged.

3. The structure of claim 1, wherein the members when bonded form a one-dimensional array.

4. The structure of claim 3, wherein the bonded members form a generally planar plate.

5. The structure of claim 4, wherein each of the members includes two hooks and two catches in back of the hooks in which hooks of other members are engaged.

6. The structure of claim 5, wherein the hooks extend at inclined angles with respect to principal surfaces of the members.

7. The structure of claim 5, wherein a radius of curvature of convex corners of the hooks is greater than a radius of curvature of corresponding concave corners of the catches.

8. The structure of claim 1, wherein the bonded members are arranged in a closed tubular shape surrounding a bore.

9. The structure of claim 1, wherein the members are silicon members.

10. The structure of claim 9, wherein the members are bonded together by a cured composite of a silica-forming agent and silicon powder disposed in the joints.

11. A tubular member extending along an axis, comprising a plurality of staves extending parallel to and arranged around the axis and including a bore extending along the axis inside of the staves, wherein neighboring ones of the staves are bonded to each other at a respective interlocking junction.

12. The member of claim 11, wherein the interlocking junction comprises hooks and catches formed in each of neighboring staves and aligned so that a catch of one of the neighboring staves accepts a hook of the other of the neighboring staves.

13. The member of claim 11, wherein the staves are silicon staves.

14. The member of claim 11, wherein the staves are bonded together by a cured composite of spin-on glass and silicon powder.

15. The member of claim 11, wherein the staves include ends comprising a circumferential neck when they are bonded together.

16. The member of claim 15, wherein the neck comprises at least three flat areas on the ends of each of the staves.

17. The member of claim 11, wherein the interlocking junction is formed from portions of the staves machined to have predetermined gaps between them.

18. The member of claim 17, wherein the staves are silicon staves bonded together by a cured composite of a silica-forming agent and silicon powder filled into the gaps.

19. A tubular member extending along a longitudinal axis and comprising a plurality of staves extending parallel to and arranged around the axis, neighboring ones of the staves being bonded to each other and including ends comprising a circumferential neck when bonded together.

20. The tubular member of claim 19, wherein the neck comprises at least three flat areas at the ends of each of the staves.

21. The tubular member of claim 19, wherein the neck is substantially circular.

22. The tubular member of claim 19, wherein the staves are silicon staves.
